(19) United States
(12) Patent Application Publication
(10) Pub. No.: US 2006/0151777 A1
(43) Pub. Date: Jul. 13, 2006

(54) Multi-layer thin film in a ballistic electron emitter

(76) Inventors: Steven L. Naberhuis, Fremont, CA (US); Huei-Pei Kuo, Cupertino, CA (US); Si-Ty Lam, Pleasanton, CA (US); Henryk Birecki, Palo Alto, CA (US); Xia Sheng, Los Altos, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/033,768

(22) Filed: Jan. 12, 2005

(51) Int. Cl. H01L 29/06

(52) U.S. Cl. 257/26

(57) ABSTRACT

An electron emitter that includes a metal film having a set of layers that are selected and arranged to adhere the metal film to a remainder of a structure of the electron emitter while avoiding electron loss in the metal film. A multiple layer metal film according to the present techniques enables a balance among adhesion properties, metal diffusion, and oxide properties that might otherwise hinder the performance of an electron emitter.

### BACKGROUND

Ballistic electron emitters may be employed in a variety of applications. For example, ballistic electron emitters may be used in lithography applications, display applications, and in storage devices.

A ballistic electron emitter may include an emitter that is embedded in a dielectric material and may further include a metal film formed on the surface of the dielectric material. An electric field may be applied across the emitter and the metal film to cause the emitter to emit electrons. The emitted electrons may accelerate through the dielectric material to the metal film under the influence of the applied electric field. The accelerated electrons may pass through the metal film and emerge as ballistic electrons.

The metal film in a prior ballistic electron emitter may be a single layer of a precious metal, e.g. gold or platinum. Unfortunately, a single metal film may not adequately adhere to a dielectric material. For example, a gold film may not maintain adequate adhesion to an oxide structure. In addition, a single precious metal film may have a relatively high resistivity and/or a relatively high work function. Unfortunately, a relatively high resistivity and/or a relatively high work function may cause a leakage current in a metal film and thereby reduce the efficiency of ballistic electrons emission from the metal film.

### SUMMARY OF THE INVENTION

An electron emitter is disclosed that includes a metal film having a set of layers that are selected and arranged to adhere the metal film to a remainder of a structure of the electron emitter while avoiding electron loss in the metal film. A multiple layer metal film according to the present techniques enables a balance among adhesion properties, metal diffusion, and oxide properties that might otherwise hinder the performance of an electron emitter.

Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIG. 1 shows an electron emitter according to the present teachings;

FIG. 2 shows one embodiment of a thin metal film that includes a top layer and a bottom layer;

FIG. 3 shows an embodiment of a thin metal film that includes a diffusion barrier between a top layer and a bottom layer;

FIG. 4 shows an embodiment of an emitter structure that includes a metal film on a substrate;

FIG. 5 shows an embodiment of an emitter structure that is a semiconductor substrate.

### DETAILED DESCRIPTION

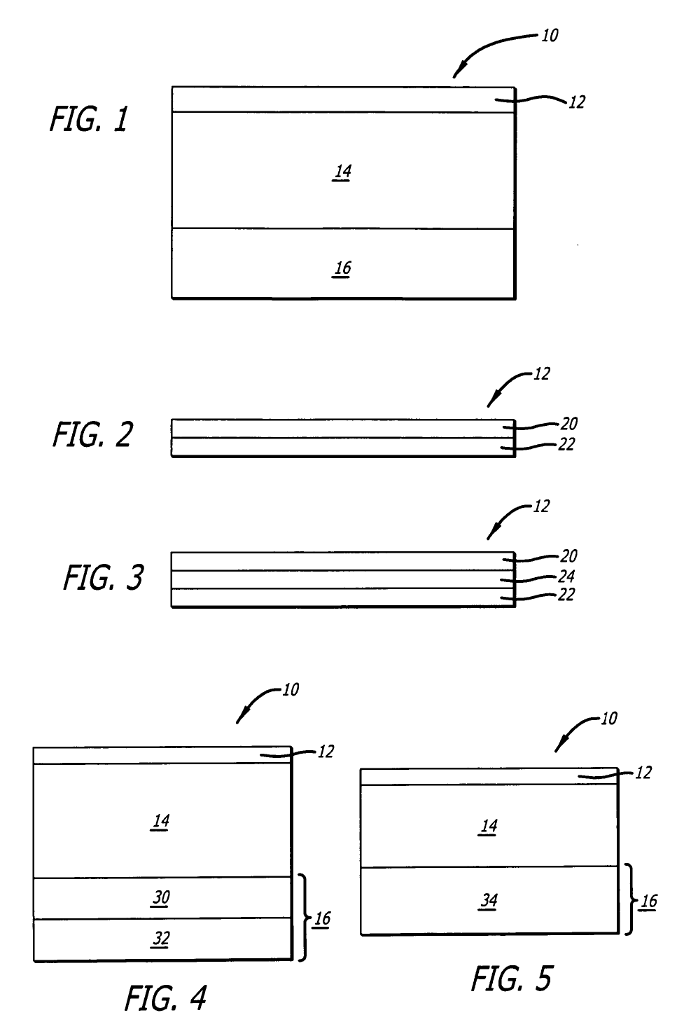

FIG. 1 shows an electron emitter 10 according to the present teachings. The electron emitter 10 includes a thin metal film 12, an intervening structure 14, and an emitter structure 16. The emitter structure 16 emits electrons when an electrical potential is applied across the metal film 12 and the emitter structure 16. The emitted electrons from the emitter structure 16 accelerate through the intervening structure 14 to the metal film 12 and emerge from the metal film 12 as ballistic electrons.

The metal film 12 includes a set of layers of materials that are selected and arranged to adhere the metal film 12 to the intervening structure 14. The layers of materials in the metal film 12 may also be selected and arranged to avoid oxidation and to avoid diffusion among the metal layers in the metal film 12.

The metal film 12 has a total thickness that is selected to avoid electron loss in the metal film 12. For example, the thickness of the metal film 12 may be selected to avoid electron loss caused by scattering as the accelerated electrons from the emitter structure 16 move through the metal film 12. In one embodiment, the metal film 12 has a total thickness less than 10 nanometers.

The intervening layer 14 may be a dielectric material. Examples dielectric materials include silicon dioxide and aluminum oxide. Alternatively, the intervening layer 14 may be a semiconductor material.

FIG. 2 shows one embodiment of the metal film 12 that includes a top layer 20 and a bottom layer 22. The materials for the top and bottom layers 20 and 22 are selected to facilitate adhesion of the metal film 12 to the intervening structure 14 and to avoid metal diffusion between the top and bottom layers 20 and 22 and to avoid oxidation.

In one embodiment, the top layer 20 is gold because gold does not readily oxidize. Other materials that may be selected for the top layer 20 because they do not readily oxidize include silver, platinum, iridium, rhodium, and palladium.

The material for the bottom layer 22 may be selected because it adheres well to the intervening structure 14 and does not react with the material of the top layer 20. In one embodiment, the bottom layer 22 is molybdenum because molybdenum adheres well to a dielectric material or a semiconductor material that may be used in the intervening structure 14 and because molybdenum is immisible with the gold material of the top layer 20. For example, molybdenum does not form inter-metallic compounds with gold.

Other materials that may be selected for the bottom layer 22 because they adhere well to silicon and oxides of silicon and because they do not form inter-metallic compounds with the materials that may be used in the top layer 20 include cobalt, nickel, rhenium, and rhodium. Chromium may be used for silver and gold top layer 20 metals as may molybdenum and tungsten. Chromium, molybdenum, and tungsten may be problematic with other top layer 20 metals due to inter-metallic compound formation that would enhance scattering and hence electron loss.

The total thickness of the top and bottom layers 20 and 22 is selected to minimize the loss of the accelerated electrons that move through the top and bottom layers 20 and 22. In one embodiment, the top and bottom layers 20 and 22 have a total thickness less than 10 nanometers.

FIG. 3 shows an embodiment of the metal film 12 that includes a diffusion barrier 24 between the top layer 20 and the bottom layer 22. The diffusion barrier 24 is a metal or conducive oxide, nitride, or carbide of a metal that prevents reactions between the metals in the top and bottom layers 20 and 22 or when the metals in the top and bottom layers 20 and 22 are miscible. The diffusion barrier 24, for example titanium nitride, may be used if the top layer 20 is gold and the bottom layer 22 is aluminum.

The top layer 20 and the bottom layer 22 and diffusion barrier 24 have a total thickness that is selected to minimize electron loss caused by scattering as the accelerated electrons from the emitter structure 16 move through. In one embodiment, top layer 20 and the bottom layer 22 and the diffusion barrier 24 have a total thickness of less than 10 nanometers.

FIG. 4 shows an embodiment of the electron emitter 10 in which the emitter structure 16 includes a metal film 30 on a substrate 32. Ballistic electrons in this embodiment are generated by applying an electrical potential across the metal film 30 and the metal film 12 which causes the metal film 30 to emit electrons that accelerate through the intervening layer 14 and emerge from the metal film 12. This embodiment of the electron emitter 10 may be referred to as a metal-insulator-metal (MIM) structure.

FIG. 5 shows an embodiment of the electron emitter 10 in which the emitter structure 16 is a semiconductor substrate 34. Ballistic electrons in this embodiment are generated by applying an electrical potential across the semiconductor substrate 34 and the metal film 12 which causes the semiconductor substrate 34 to emit electrons that accelerate through the intervening layer 14 and emerge from the metal film 12. This embodiment of the electron emitter 10 may be referred to as a metal-insulator-semiconductor (MIS) structure.

The layers of the metal film 12 may be deposited by sputtering. For example, the kinetic energy of material deposition provided by sputtering may increase the adhesion of the metal film 12 to the intervening layer 14. Alternatively, the layers of the metal film 12 may be deposited using evaporation or chemical vapor deposition or other such means.

The foregoing detailed description of the present invention is provided for the purposes of illustration and is not intended to be exhaustive or to limit the invention to the precise embodiment disclosed. Accordingly, the scope of the present invention is defined by the appended claims.

What is claimed is:

1. An electron emitter comprising a metal film having a set of layers that are selected and arranged to adhere the metal film to a remainder of a structure of the electron emitter.

2. The electron emitter of claim 1, wherein the layers include a top layer that is selected in response to an oxidizing property.

3. The electron emitter of claim 2, wherein the layers include a bottom layer that is selected in response to an adhesion property.

4. The electron emitter of claim 2, wherein the layers include a bottom layer that is selected in response to inter-metallic compound formation with the top layer.

5. The electron emitter of claim 2, wherein the layers include a bottom layer that is selected in response to an adhesion property to the structure and in response to inter-metallic compound formation with the top layer.

6. The electron emitter of claim 2, wherein the layers include a bottom layer and a diffusion barrier interposed between the bottom and top layers that avoids an inter-metal reaction of the top and bottom layers.

7. The electron emitter of claim 2, wherein the layers include a bottom layer that is selected in response to an adhesion property to the structure and a diffusion barrier interposed between the bottom and top layers that avoids an inter-metal reaction of the top and bottom layers.

8. The electron emitter of claim 1, wherein the layers include a pair of layers that are selected to avoid diffusion between the layers.

9. The electron emitter of claim 8, wherein the layers have a total thickness that is selected to minimize electron loss in the metal film.

10. The electron emitter of claim 8, wherein the layers have a total thickness less than ten nanometers.

11. A method for forming an electron emitter comprising forming a set of layers of a metal film on a remainder of a structure of the electron emitter such that the layers are selected and arranged to adhere the metal film to the remainder of the structure.

12. The method of claim 11, wherein forming a set of layers includes forming a top layer that is selected in response to an oxidizing property.

13. The method of claim 12, wherein forming a set of layers includes forming a bottom layer that is selected in response to an adhesion property.

14. The method of claim 12, wherein forming a set of layers includes forming a bottom layer that is selected in response to inter-metallic compound formation with the top layer.

15. The method of claim 12, wherein forming a set of layers includes forming a bottom layer that is selected in response to an adhesion property to the structure and in response to inter-metallic compound formation with the top layer.

16. The method of claim 12, wherein forming a set of layers includes forming a bottom layer and forming a diffusion barrier interposed between the bottom and top layers that avoids an inter-metal reaction of the top and bottom layers.

17. The method of claim 12, wherein forming a set of layers includes forming a bottom layer that is selected in response to an adhesion property to the structure and forming a diffusion barrier interposed between the bottom and top layers that avoids an inter-metal reaction of the top and bottom layers.

18. The method of claim 11, wherein forming a set of layers includes forming a pair of layers that are selected to avoid diffusion between the layers.

19. The method of claim 18, wherein forming a pair of layers includes forming a pair of layers that have a total thickness that is selected to minimize electron loss in the metal film.

20. The method of claim 18, wherein forming a pair of layers includes forming a pair of layers that have a total thickness less than ten nanometers.
